(19) United States
(12) Patent Application Publication
(10) Pub. No.: US 2023/0374661 A1
(43) Pub. Date: Nov. 23, 2023

(54) SHOWERHEAD WITH INTEGRAL DIVERT FLOW PATH

(71) Applicant: LAM RESEARCH CORPORATION, Fremont, CA (US)

(72) Inventors: Gopinath BHIMARASETTI, Portland, OR (US); Aaron Blake MILLER, West Linn, OR (US); Rachel E. BATZER, Tigard, OR (US)

(21) Appl. No.: 18/029,963

(22) PCT Filed: Sep. 30, 2021
(86) PCT No.: PCT/US2021/052785

§ 371 Date: Apr. 3, 2023

Related U.S. Application Data
(60) Provisional application No. 63/088,940, filed on Oct. 7, 2020.

(51) Int. Cl. C23C 16/455; C23C 16/44

(52) U.S. Cl. CPC C23C 16/45565; C23C 16/4412

(57) ABSTRACT

A showerhead for a processing chamber comprises a body having upper, lower, and side surfaces defining a plenum; and a plurality of through holes provided on the lower surface of the body. The plurality of through holes are in fluid communication with the plenum and the processing chamber. The showerhead comprises an inlet provided on one of the upper and side surfaces of the body and a first passage provided in the body. The first passage connects the inlet to the plenum. The showerhead comprises an outlet provided on one of the upper and side surfaces of the body and a second passage provided in the body. The second passage connects the outlet to the plenum.

### CROSS-REFERENCE TO RELATED APPLICATIONS

This application claims the benefit of U.S. Provisional Application No. 63/088,940, filed on Oct. 7, 2020. The entire disclosure of the application referenced above is incorporated herein by reference.

### FIELD

The present disclosure relates generally to substrate processing systems and more particularly to a showerhead design with an integral flow path for diverting gases to minimize dead leg.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems for performing deposition and/or etching typically include a processing chamber with a pedestal. A substrate such as a semiconductor wafer may be arranged on the pedestal during processing. A gas delivery system may introduce a process gas mixture including one or more precursors into the processing chamber to deposit a film on the substrate or to etch the substrate. In some substrate processing systems, material is deposited on the substrate using an atomic layer deposition (ALD) process. In some substrate processing systems, plasma can be struck in the processing chamber and/or an RF bias on the pedestal may be used to activate chemical reactions.

Various gas flow paths in the gas delivery system are used to deliver process gases, carrier gases, oxidizing gases, precursor gases, and/or purge gases to the processing chamber. The gas flow paths are defined by via tubing, valves, manifolds and so on. A first gas may be delivered by a gas flow channel during a first portion of a process and gas may not be delivered or a second gas may be delivered during a second portion of the process. The first gas may remain in the gas flow channel temporarily unless a purge process is performed to clear the gas flow channel. Portions of gas flow channels that hold stagnant gases are called dead legs. Stagnant gases in the dead legs may decompose and cause defects on the substrate.

### SUMMARY

A showerhead for a processing chamber comprises a body having upper, lower, and side surfaces defining a plenum; and a plurality of through holes provided on the lower surface of the body. The plurality of through holes are in fluid communication with the plenum and the processing chamber. The showerhead comprises an inlet provided on one of the upper and side surfaces of the body and a first passage provided in the body. The first passage connects the inlet to the plenum. The showerhead comprises an outlet provided on one of the upper and side surfaces of the body and a second passage provided in the body. The second passage connects the outlet to the plenum.

In another feature, the outlet is downstream relative to the inlet and is in fluid communication with the inlet.

In another feature, the inlet and the outlet are located on opposite ends of the showerhead.

In another feature, the inlet and the outlet are connected to opposite ends of the plenum.

In another feature, the inlet and the outlet are located on opposite ends of the showerhead and are connected to opposite ends of the plenum.

In other features, a system comprises the showerhead and first and second valves respectively connected to the inlet and the outlet. The first valve is connected to a gas supply. The second valve is connected to an exhaust of the processing chamber.

In another feature, the system further comprises a controller configured to close the second valve and open the first valve to supply a first gas from the gas supply to the inlet, open the second valve when subsequently supplying a second gas instead of the first gas from the gas supply to the inlet via the first valve, and close the second valve after a predetermined time.

In another feature, the side surface extends perpendicularly towards a bottom of the processing chamber, and the outlet is located on a bottom end of the side surface.

In another feature, the bottom end of the side surface extends past at least a portion of a pedestal arranged in the processing chamber.

In other features, a system comprises the showerhead and first and second valves respectively connected to the inlet and the outlet. The first valve is connected to a gas supply. The second valve is in fluid communication with an exhaust of the processing chamber.

In another feature, the system further comprises a controller configured to close the second valve and open the first valve to supply a first gas from the gas supply to the inlet, open the second valve when subsequently supplying a second gas instead of the first gas from the gas supply to the inlet via the first valve, and close the second valve after a predetermined time.

In another feature, the lower surface is attached to a sidewall of the processing chamber.

In another feature, the outlet is located on a bottom end of the sidewall.

In other features, a system comprises the showerhead and first and second valves respectively connected to the inlet and the outlet. The first valve is connected to a gas supply. The second valve is in fluid communication with an exhaust of the processing chamber located at a bottom of the processing chamber.

In another feature, the system further comprises a controller configured to close the second valve and open the first valve to supply a first gas from the gas supply to the inlet, open the second valve when subsequently supplying a second gas instead of the first gas from the gas supply to the inlet via the first valve, and close the second valve after a predetermined time.

In another feature, the showerhead is mounted to a top plate of the processing chamber and has a greater diameter than a pedestal arranged in the processing chamber.

In other features, a system comprises the showerhead and first and second valves arranged on the top plate and are respectively connected to the inlet and the outlet. The first valve is connected to a gas supply. The second valve is connected to an exhaust of the processing chamber.

In another feature, the system further comprises a controller configured to close the second valve and open the first valve to supply a first gas from the gas supply to the inlet, open the second valve when subsequently supplying a second gas instead of the first gas from the gas supply to the inlet via the first valve, and close the second valve after a predetermined time.

In other features, a system comprises the showerhead and a first valve arranged on the top plate. The first valve is connected to the inlet and to a gas supply. The outlet is located on a periphery of the showerhead.

In another feature, the system further comprises a second valve connected to the outlet. The second valve is in fluid communication with an exhaust of the processing chamber located at a bottom of the processing chamber.

In another feature, the system further comprises a controller configured to close the second valve and open the first valve to supply a first gas from the gas supply to the inlet, open the second valve when subsequently supplying a second gas instead of the first gas from the gas supply to the inlet via the first valve, and close the second valve after a predetermined time.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIGS. 1A and 1B show an example of a substrate processing system comprising a processing chamber including a showerhead according to the present disclosure;

FIG. 2 shows an example of a showerhead with a gas divert path upstream from the showerhead;

FIG. 3A shows an example of a showerhead with a bore and with a gas divert path downstream from the showerhead according to the present disclosure;

FIGS. 3B and 3C show an example of a showerhead with a bore and with a gas divert path through the bottom of the bore according to the present disclosure;

FIG. 4A shows an example of a bore-less showerhead with chamber walls defining a bore and with a gas divert path downstream from the showerhead according to the present disclosure;

FIG. 4B shows an example of a bore-less showerhead with chamber walls defining a bore and with a gas divert path through the bottom of the bore according to the present disclosure;

FIG. 5A shows an example of a showerhead mounted to a top of a processing chamber and with a gas divert path through the top of the processing chamber and downstream from the showerhead according to the present disclosure;

FIG. 5B shows an example of a showerhead mounted to a top of a processing chamber and with a gas divert path downstream from the showerhead opening into the processing chamber according to the present disclosure; and

FIG. 6 shows a method of operating the showerheads of FIGS. 3A-5B and providing a gas divert path downstream from the showerheads according to the present disclosure.

In the drawings, reference numbers may be reused to identify similar and/or identical elements.

### DETAILED DESCRIPTION

Showerheads are typically designed to provide uniform flow distribution of gases to a substrate in a processing chamber. Uniform flow distribution is achieved by restricting gas flow from a plenum in the showerhead to a plurality of holes in a faceplate of the showerhead. However, restricting gas flow in this manner is problematic for quickly purging and/or transitioning from supplying one gas to another in processes such atomic layer deposition (ALD) processes. There is a direct trade-off between rapid ALD cycling/transitioning and uniformity. When one is improved, the other is generally worsened.

Typically, the entire gas flow is distributed to the holes in the faceplate of the showerhead, and all gases exit through the holes into the processing chamber towards the substrate. Throughout the present disclosure, the flow of gases exiting the holes of the showerhead into the processing chamber is called a push, and the volume of gases that exits the holes of the showerhead into the processing chamber and that exists between the showerhead and the substrate is called a process volume.

In ALD processes, gas cycles/transitions occur frequently (e.g., on the order of 100-2,000 times per substrate). A single step in an ALD cycle may be on the order of 0.1-10 seconds. A transition from gas A to gas B occurs by pushing gas A through the showerhead plenum with gas B to purge or exhaust gas A from the showerhead plenum. Specifically, to transition from gas A to gas B, gas A is pushed out of the plenum in the showerhead using gas B, through the holes of the showerhead, and into the process volume. A minimal amount of dead volume between a valve controlling the cycling (hereinafter called the ALD valve) and the showerhead helps to make this process faster. Accordingly, the ALD valve is placed as close to the showerhead inlet as feasible.

However, this still leaves the volume between the ALD valve and the substrate as the dead volume, which is defined almost entirely by the showerhead geometry. For example, a delivery line from a gas box to the ALD valve may have a volume generally on the order of 100-400 cc; the showerhead volume may be generally on the order of 300-600 cc for ALD processes; and the showerhead holes may have a volume on the order of 2-10 cc. Accordingly, diverting gas flow after the plenum volume and before the holes of the showerhead can significantly improve (i.e., reduce) cycling time.

In addition to longer ALD cycling times, the transition phase between gas cycles and flow conditions have a negative impact on process performance. Gas flow through the showerhead is relatively non-uniform as the gas flow develops into a saturated, steady-state condition. This non-uniformity of gas flow affects substrate uniformity, especially for processes that are sensitive to gas flow uniformity. Accordingly, if the transition phase of the gas flow is diverted away from the substrate, and the substrate is then only exposed to a fully developed gas flow, the substrate uniformity can also be improved in addition to improving cycling time.

The present disclosure provides an exit path from the showerhead plenum to the chamber exhaust that diverts gas flow away from the process volume and that represents a less-restrictive path relative to the hole pattern of the showerhead. Throughout the present disclosure, the flow of gases diverted away from the holes of the showerhead and from the process volume via the exit path downstream from the showerhead plenum to the chamber exhaust is called a pull.

Some substrate processing systems according to the present disclosure include a showerhead with an inlet POC (point of connection) from the ALD valve located near an edge or center of the processing chamber. The gas received from the ALD valve at the inlet is distributed to a pre-distribution plenum, a primary plenum, the showerhead holes, and the substrate, in that order. A post-distribution plenum which is equal and opposite in shape relative to the primary plenum can be provided according to the present disclosure. The post-distribution plenum can lead to a divert line extending directly to the chamber exhaust. The divert line POC can be on the opposite edge of the showerhead from the inlet POC although the divert line POC can be located elsewhere. Throughout the present disclosure, an arrangement of two elements in which the two elements are described as being located opposite to each other includes an arrangement in which the two elements are located 180 degrees apart from each other and also includes other alternative arrangements of the two elements.

Since the primary plenum represents a pressure drop approximately 10×less than that of the showerhead holes (constituting 10× less restriction), the gas can flow through the post-distribution plenum if the divert path through the post-distribution plenum is open. In some implementations, the present disclosure provides a controlling valve for the post-distribution plenum that can open to divert the gas flow through the post-distribution plenum at the right stage of the ALD cycle.

In another implementation, the gas flow can be diverted from the showerhead plenum through a passage leading to the bottom of the showerhead bore as explained below. Since the bore terminates below the process volume (below the pedestal), any gas that is diverted to the bottom of the showerhead bore can therefore be directed into the chamber exhaust without affecting the substrate. In this approach, a valve can be installed inside the processing chamber to control the opening and closing of the passage.

Accordingly, while in some systems for diverting waste gas, the diversion occurs at a valve manifold block located upstream from the showerhead, which leaves the showerhead as a dead volume, the present disclosure provides a divert path that is integral to the showerhead and that is downstream from the showerhead. Specifically, instead of diverting gas upstream from the showerhead, the present disclosure provides a divert path for the gas in the showerhead plenum to exit the showerhead such that the diverted gas does not flow to the substrate (i.e., the divert path does not go to the process volume). The divert path is connected fluidly to the showerhead plenum and allows for the gas in the plenum to leave the plenum downstream relatively quickly. The divert path represents a minimal dead-leg between the divert valve location and the process volume, leaving only the showerhead holes instead of the entire showerhead as a dead leg.

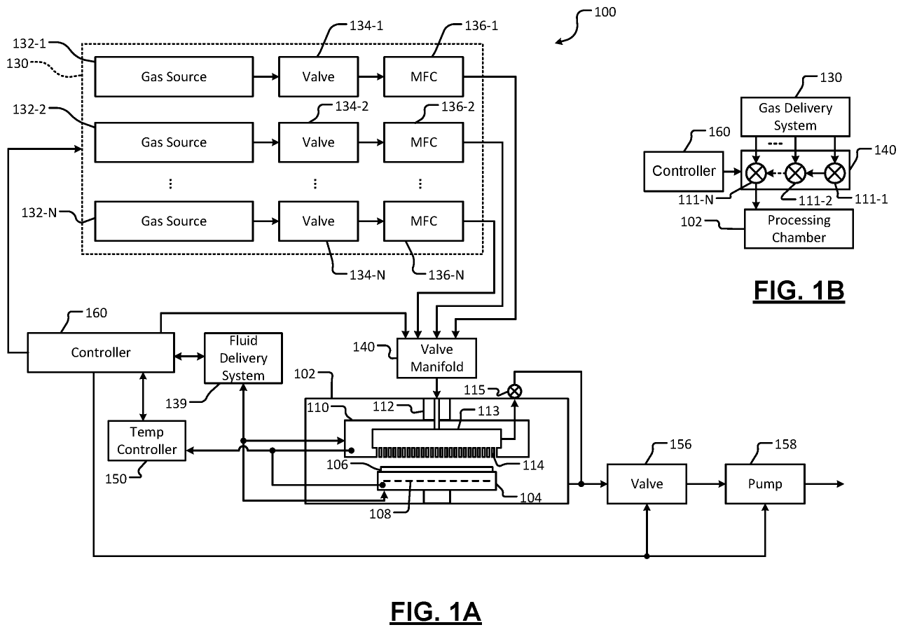

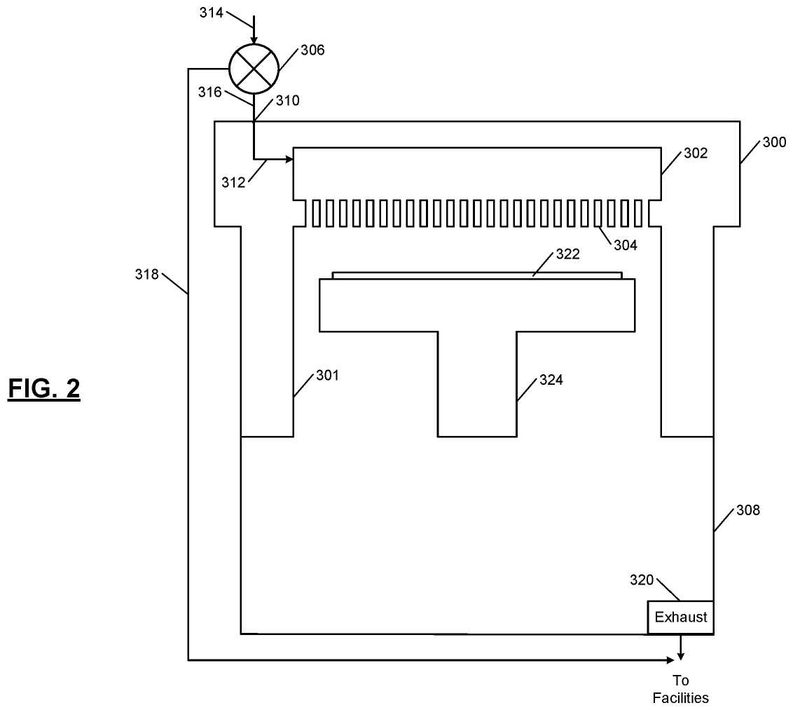

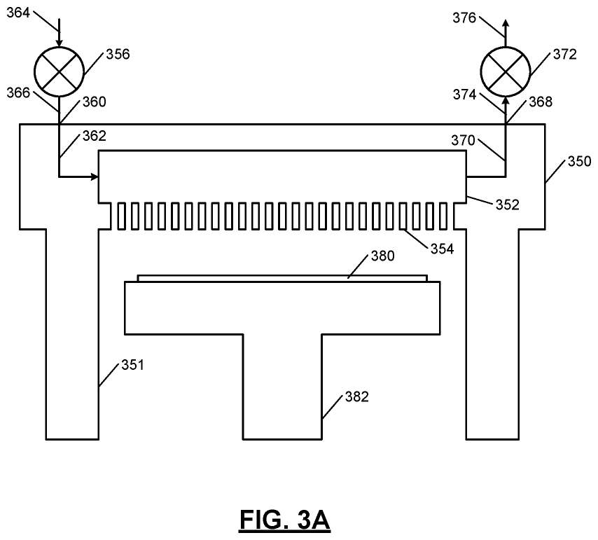

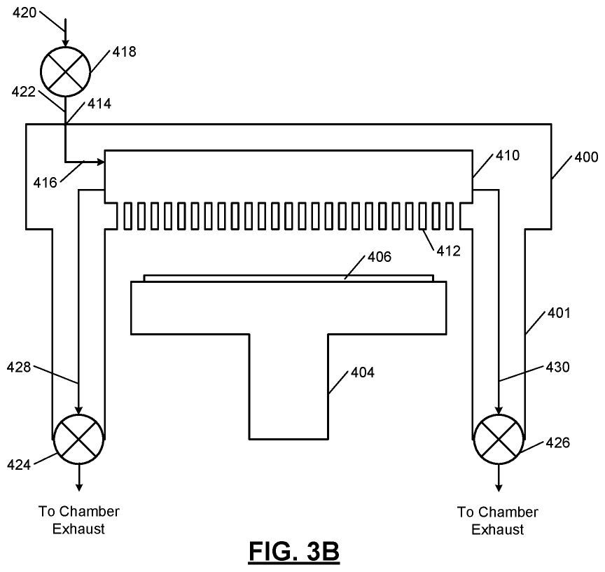

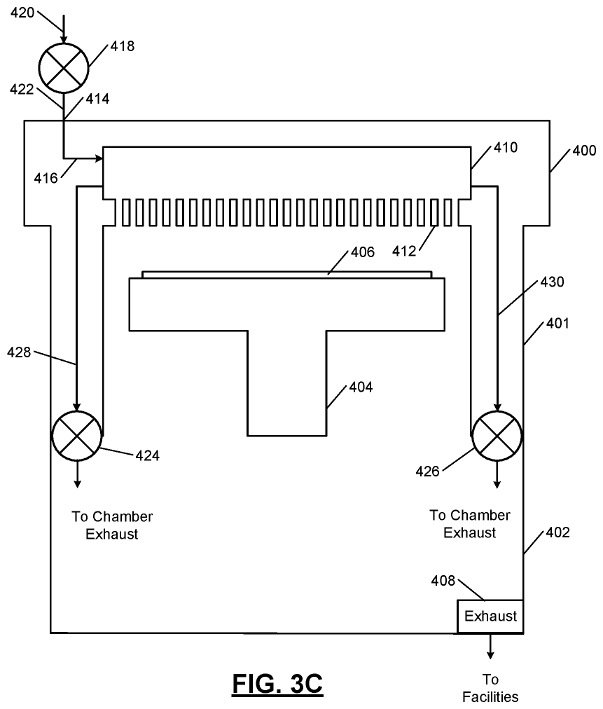

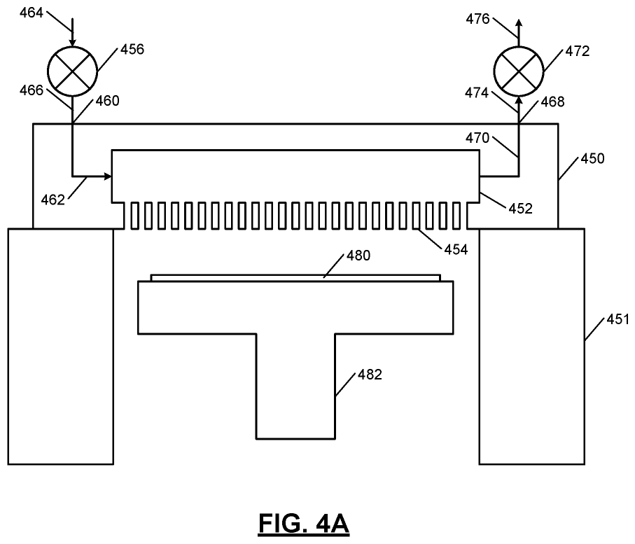

The present disclosure is organized as follows. Initially, an example of a substrate processing system in which the showerheads designed according to the present disclosure can be used is shown and described with reference to FIGS. 1A and 1B. An example of a gas divert path upstream from the showerhead is shown and described with reference to FIG. 2. Thereafter, examples of various showerhead configurations including a gas divert path designed according to the present disclosure are shown and described with reference to FIGS. 3A-5B. Subsequently, method of operating the showerheads shown in FIGS. 3A-5B and providing a gas divert path according to the present disclosure is shown and described with reference to FIG. 6.

FIGS. 1A and 1B show an example of a substrate processing system 100 comprising a processing chamber 102 configured to process a substrate using thermal atomic layer deposition (T-ALD). The processing chamber 102 encloses other components of the substrate processing system 100. The processing chamber 102 comprises a substrate support (e.g., a pedestal) 104. During processing, a substrate 106 is arranged on the pedestal 104.

One or more heaters 108 (e.g., a heater array) may be disposed in a ceramic plate arranged on a metallic baseplate of the pedestal 104 to heat the substrate 106 during processing. One or more additional heaters called zone heaters or primary heaters (not shown) may be arranged in the ceramic plate above or below the heaters 108. Additionally, while not shown, a cooling system comprising cooling channels through which a coolant can be flowed to cool the pedestal 104 may be disposed in the baseplate of the pedestal 104; and one or more temperature sensors may be disposed in the pedestal 104 to sense the temperature of the pedestal 104.

The processing chamber 102 comprises a gas distribution device 110 such as a showerhead to introduce and distribute process gases into the processing chamber 102. Various examples of showerhead configurations designed according to the present disclosure are shown and described in detail with reference to FIGS. 3A-5B. In one example shown, the showerhead 110 may include a stem portion 112 having one end connected to a top surface of the processing chamber 102. A base portion of the showerhead 110 is generally cylindrical and extends radially outwardly from an opposite end of the stem portion 112 at a location that is spaced from the top surface of the processing chamber 102. The base portion includes a plenum 113 and a faceplate 114 including plurality of outlets or features (e.g., slots or through holes) to disperse gases towards the substrate 106.

Further, while not shown, the showerhead 110 may comprise heating and cooling plates. The heating plate may include one or more heaters, and the cooling plate may include a cooling channel through which a coolant can be circulated. Additionally, one or more temperature sensors may be disposed in the showerhead 110 to sense the temperature of the showerhead 110.

A gas delivery system 130 comprises one or more gas sources 132-1, 132-2, . . . , and 132-N (collectively gas sources 132), where N is an integer greater than one. The gas sources 132 may supply process gases, cleaning gases, purge gases, inert gases, and so on. The gas sources 132 are connected by valves 134-1, 134-2, . . . , and 134-N (collectively valves 134) and mass flow controllers 136-1, 136-2, . . . , and 136-N (collectively mass flow controllers 136) to a valve manifold 140. In an example shown in FIG. 1B, the valve manifold 140 comprises a plurality valves 111-1, 111-2, . . . , and 111-N (collectively valves 111) that can be controlled to supply one or more gases from the gas sources 132 to the showerhead 110. The valve manifold 140 is located proximate to the processing chamber 102 so that when a mixture of the gases is used, the mixing of the gases, which occurs in the valve manifold 140, occurs as close to the point of entry into the processing chamber 102 as possible. An output of the valve manifold 140 is connected to the showerhead 110. A second valve 115 connects a divert path from the plenum 113 to the chamber exhaust as explained below in detail. In some processes, while not shown, a remotely generated plasma may be supplied to the processing chamber 102.

A fluid delivery system 139 supplies a coolant to the cooling system in the pedestal 104 and to the cooling channel in the showerhead 110. A temperature controller 150 may be connected to the heaters 108, the zone heaters, and the temperature sensors in the pedestal 104, and to the heating plate and the temperature sensors in the showerhead 110. The temperature controller 150 may control power supply to the heaters 108 and the zone heaters, and coolant flow through the cooling system in the pedestal 104 to control the temperature of the pedestal 104 and the substrate 106. The temperature controller 150 may also control power supply to the heaters disposed in the heating plate of the showerhead 110 and coolant flow through the cooling channel disposed in the cooling plate of the showerhead 110 to control the temperature of the showerhead 110.

A valve 156 and pump 158 may be used to maintain sub-atmospheric pressure inside the processing chamber 102 during substrate processing and to evacuate reactants from the processing chamber 102. A system controller 160 controls the components of the substrate processing system 100 including the valves 111 in the valve manifold 140 and the second valve 115 as described below in detail.

Throughout the following description, an inlet of a showerhead is shown and described as being connected to an ALD valve that is connected to a gas supply (e.g., element 130 shown in FIG. 1A) via a gas line. Instead, the inlet may be connected to a valve manifold (e.g., element 140 shown in FIG. 1A) comprising a plurality of valves (e.g., elements 111 shown in FIG. 1B) connected to a plurality of gas sources via a plurality of gas lines, respectively; and one or more valves in the valve manifold may be controlled and operated as described below with reference to the ALD valve.

FIG. 2 shows an example of a showerhead 300 with a gas divert path upstream of the showerhead 300. The showerhead 300 with a bore 301 comprises a plenum 302 and a faceplate 304 including a plurality of outlets or features (e.g., slots or through holes). A valve (called an ALD valve as described above) 306 connected to a gas supply via a first gas line 314 is arranged at an edge or near the center of a processing chamber 308 proximate to an inlet 310 of the showerhead 300. The inlet 310 is proximate to the plenum 302. A passage 312 in the showerhead 300 between the inlet 310 and the plenum 302 connects the inlet 310 to the plenum 302.

A first port of the ALD valve 306 is connected to a gas supply via a first gas line 314. A second port of the ALD valve 306 is connected to the inlet 310 via a second gas line 316. A third port of the ALD valve 306 is connected via a third gas line (called a gas divert path) 318 to exhaust facilities to which a chamber exhaust 320 is connected.

During ALD processing, in each ALD cycle, the showerhead 300 receives gas A followed by gas B from the gas supply via the ALD valve 306 through the first and second gas lines 314, 316. The gases enter the showerhead 300 through the inlet 310 and the passage 312 into the plenum 302 of the showerhead 300.

When receiving each gas, the first and second ports of the ALD valve 306 are open, and the third port of the ALD valve 306 is closed. The showerhead 300 disperses each gas from the plenum 302 through the outlets in the faceplate 304 towards a substrate 322 arranged on a pedestal 324 in the processing chamber 308.

When transitioning from gas A to gas B in an ALD cycle, gas B is flowed through the first and second ports of the ALD valve 306, and the third port of the ALD valve 306 connected to the gas divert path 318 is opened to divert gas A into the exhaust facilities to which the chamber exhaust 320 is connected. Subsequently, the third port of the ALD valve 306 is closed, and gas B is dispersed from the plenum 302 via the outlets in the faceplate 304 towards the substrate 322. The process is repeated when transitioning from gas B to gas A.

In the showerhead 300, the entire gas flow in the plenum 302 is distributed to the holes in the faceplate 304, and all gases exit through the holes in the faceplate 304 into the processing chamber 308 towards the substrate 322. To transition from gas A to gas B, initially gas B pushes gas A out of the plenum 302 through the holes in the faceplate 304 into the process volume (region between the faceplate 304 of the showerhead and the substrate 322), and then gas B flows from the plenum 302 through the holes in the faceplate 304 into the process volume.

The ALD valve 306 is placed as close to the gas inlet 310 of the showerhead 300 as feasible to minimize the amount of dead volume between the ALD valve 306 and the showerhead 300. However, this still leaves the volume between the ALD valve 306 and the substrate 322 as the dead volume, which is defined almost entirely by the geometry of the showerhead 300.

FIGS. 3A-5B show various examples of showerhead designs according to the present disclosure that include a gas divert path downstream from the plenum of the showerhead instead of upstream from the showerhead. Diverting gas flow after the plenum volume and before the holes of the showerhead significantly improves (i.e., reduce) cycling time and uniformity.

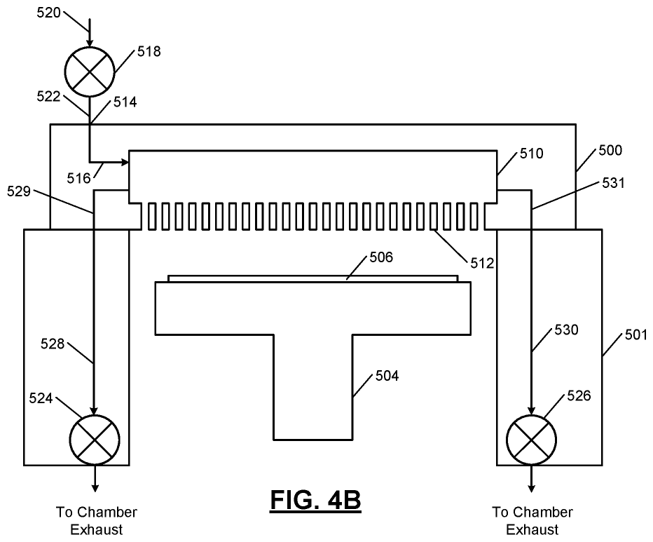

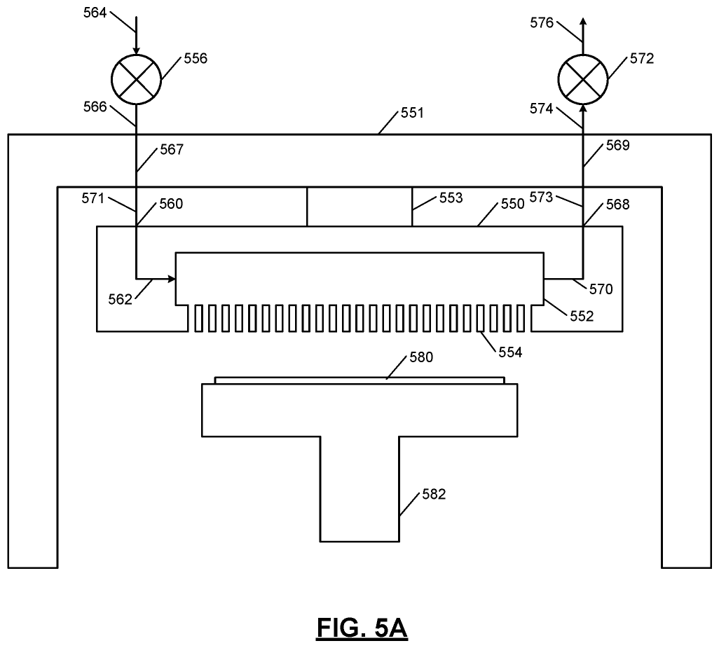

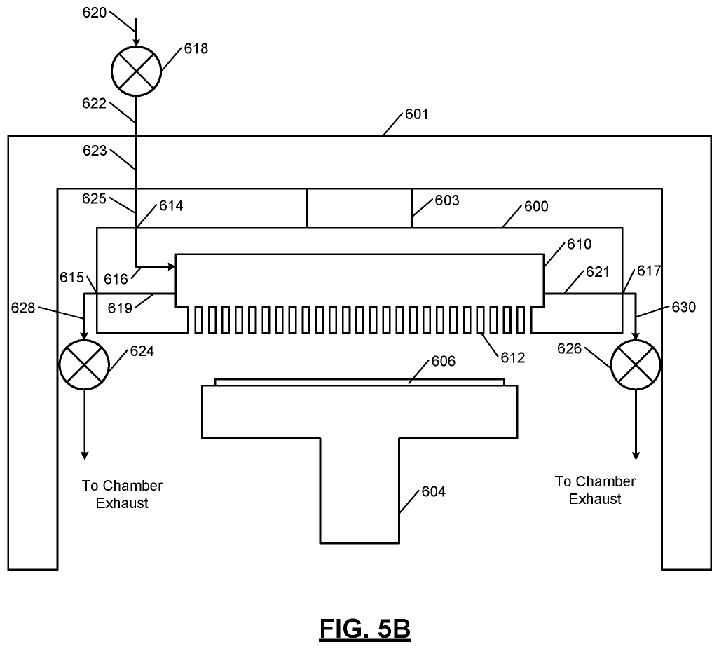

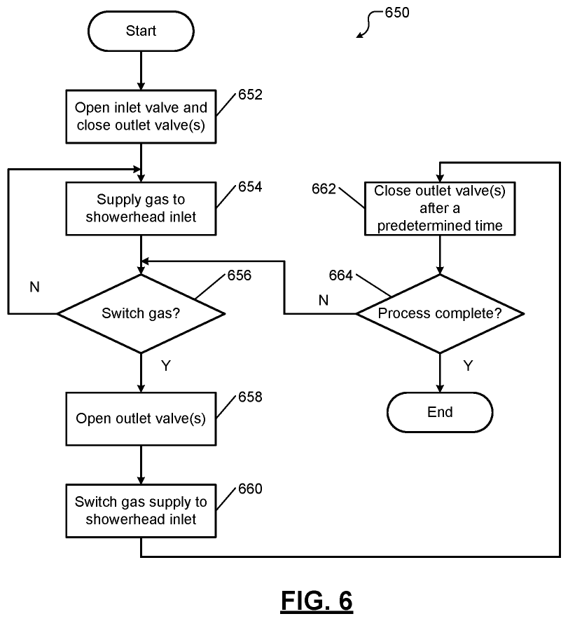

FIGS. 3A-3C show a showerhead with a bore. FIGS. 4A and 4B show a bore-less showerhead, with walls of a processing chamber defining a bore. FIGS. 5A and 5B show a showerhead attached to the top of the processing chamber (e.g., either mounted directly to the top of the processing chamber or using a stem portion like a chandelier). Each of these configurations with respective gas divert paths are now described in further detail.

FIG. 3A shows an example of a showerhead 350 with a bore 351 and with a gas divert path downstream from a plenum 352 of the showerhead 350 according to the present disclosure. The showerhead 350 comprises a plenum 352 and a faceplate 354 including a plurality of outlets or features (e.g., slots or through holes).

A first valve (also called an ALD valve as described above) 356 is arranged at an edge or the center of a processing chamber (e.g., element 102 shown in FIG. 1A) proximate to an inlet 360 of the showerhead 350. The inlet 360 is proximate to the plenum 352. A first passage 362 in the showerhead 350 between the inlet 360 and the plenum 352 connects the inlet 360 to the plenum 352.

A first port of the first valve 356 is connected to a gas supply (e.g., element 130 shown in FIG. 1A) via a first gas line 364. A second port of the first valve 356 is connected to the inlet 360 via a second gas line 366. The first valve 356 is not connected to the exhaust facilities to which a chamber exhaust (e.g., similar to element 320 shown in FIG. 2) is connected.

The showerhead 350 includes an outlet 368 at an opposite end relative to the inlet 360. The outlet 368 is proximate to the plenum 352. A second valve 372 is arranged at an opposite end of the showerhead 350 relative to the first valve 356. The second valve 372 is proximate to the edge of the processing chamber. A second passage 370 in the showerhead 350 between the outlet 368 and the plenum 352 connects the outlet 368 to the plenum 352. A first port of the second valve 372 is connected to the outlet 368 via a third gas line 374. A second port of the second valve 372 is connected via a fourth gas line 376 to the exhaust facilities to which the chamber exhaust is connected.

The second passage 370, the third gas line 374, and the second valve 372 constitute a gas divert path for the showerhead 350. The gas divert path formed by the second passage 370, the third gas line 374, and the second valve 372 (hereinafter the gas divert path 370, 374, 372) is integral to the showerhead 350 and is downstream from the plenum 352 of the showerhead 350.

During ALD processing, in each ALD cycle, the showerhead 350 receives gas A followed by gas B from the gas supply via the first valve 356 through the first and second gas lines 364, 366. The gases enter the showerhead 350 through the inlet 360 and the first passage 362 into the plenum 352 of the showerhead 350. A controller (e.g., element 160 shown in FIG. 1A) controls the first and second valves 356, 372 and operates the ports of the first and second valves 356, 372 as follows.

When receiving each gas, the first and second ports of the first valve 356 are open, and the first port of the second valve 372 is closed. The second port of the second valve 372 may be open or closed. The showerhead 350 disperses each gas via the outlets in the faceplate 354 towards a substrate 380 arranged on a pedestal 382 in the processing chamber.

When transitioning from gas A to gas B in an ALD cycle, gas B is flowed through the first and second ports of the first valve 356, the first and second gas lines 364, 366, the inlet 360, and the first passage 362 into the plenum 352. The first port (and the second port, if closed) of the second valve 372 is/are opened to connect the plenum 352 to the gas divert path 370, 374, 372. The residual gas A in the plenum 352 is diverted through the gas divert path 370, 374, 372 and via the fourth gas line 376 into the exhaust facilities.

During the transition, the gas divert path 370, 374, 372 diverts gas flow away from the process volume to the chamber exhaust and represents a less-restrictive path to the chamber exhaust relative to the hole pattern of the showerhead 350. Subsequently, the first port (and optionally the second port) of the second valve 372 is closed, and gas B is dispersed from the plenum 352 via the outlets in the faceplate 354 towards the substrate 380. The process is repeated when transitioning from gas B to gas A.

During each transition, the gas divert path 370, 374, 372 provides a path for the gas in the plenum 352 to exit the showerhead 350 such that the path does not go to the substrate 380 (i.e., does not go to the process volume between the showerhead 350 and the substrate 380). The gas divert path 370, 374, 372 allows for the gas in the plenum 352 to leave the plenum 352 downstream relatively quickly and represents a minimal dead-leg between the second valve 372 and the process volume, leaving only the volume of the holes in the faceplate 354, instead of the entire showerhead 350, as a dead leg.

FIGS. 3B and 3C show an example of a showerhead 400 with a bore 401 and with a gas divert path through valves at the bottom of the bore 401 of the showerhead 400 according to the present disclosure. In FIG. 3C, an outer diameter of the bore 401 is approximately the same as the diameter of the sidewall of a processing chamber 402 (e.g., element 102 shown in FIG. 1A). During transition, the gas exits through the valves at the bottom of the bore 401 into a region of the processing chamber 402 below a pedestal 404 arranged in the processing chamber 402. Since the gas exits though the bottom of the bore 401 into the region below the pedestal 404, the gas exiting from the gas divert path does not react with a substrate 406 arranged on the pedestal 404. Instead, the gas from the gas divert path exits the processing chamber 402 through a chamber exhaust 408.

In FIG. 3B, the showerhead 400 comprises a plenum 410 and a faceplate 412 including a plurality of outlets or features (e.g., slots or through holes). The showerhead 400 comprises an inlet 414 proximate to the plenum 410. A first passage 416 in the showerhead 400 between the inlet 414 and the plenum 410 connects the inlet 414 to the plenum 410.

A first valve (also called an ALD valve as described above) 418 is arranged at an edge or the center of the processing chamber 402 proximate to the inlet 414 of the showerhead 400. A first port of the first valve 418 is connected to a gas supply (e.g., element 130 shown in FIG. 1A) via a first gas line 420. A second port of the first valve 418 is connected to the inlet 414 via a second gas line 422. The first valve 418 is not connected to the exhaust facilities to which the chamber exhaust 408 is connected.

A second valve 424 and a third valve 426 are arranged at the bottom of the bore 401 at opposite ends of the bore 401. Second and third passages 428 and 430 in the bore 401 between the plenum 410 and the first ports of the second and third valves 424, 426 respectively connect opposite ends of the plenum 410 to the first ports of the second and third valves 424, 426. Second ports of the second and third valves 424, 426 are configured to open into the processing chamber 402 and are in fluid communication with the chamber exhaust 408 connected to the exhaust facilities.

The second and third passages 428, 430 and the second and third valves 424, 426 constitute gas divert paths for the showerhead 400. The gas divert paths formed by the second and third passages 428, 430 and the second and third valves 424, 426 (hereinafter the gas divert paths 428, 424, 430, 426) are integral to the showerhead 400 and are downstream from the plenum 410 of the showerhead 400.

During ALD processing, in each ALD cycle, the showerhead 400 receives gas A followed by gas B from the gas supply via the first valve 418 through the first and second gas lines 420, 422. The gases enter the showerhead 400 through the inlet 414 and the first passage 416 into the plenum 410 of the showerhead 400. A controller (e.g., element 160 shown in FIG. 1A) controls the first, second, and third valves 418, 424, 426 and operates the ports of the first, second, and third valves 418, 424, 426 as follows.

When receiving each gas, the first and second ports of the first valve 418 are open, and the first ports of the second and third valves 424, 426 are closed. The second ports of the second and third valves 424, 426 may be open or closed. The showerhead 400 disperses each gas via the outlets in the faceplate 412 towards the substrate 406 arranged on the pedestal 404 in the processing chamber 402.

When transitioning from gas A to gas B in an ALD cycle, gas B is flowed through the first and second ports of the first valve 418, the first and second gas lines 420, 422, the inlet 414, and the first passage 416 into the plenum 410. The first ports (and the second ports, if closed) of the second and third valves 424, 426 are opened to connect the plenum 410 to the gas divert path gas divert paths 428, 424, 430, 426. The residual gas A in the plenum 410 is diverted through the gas divert paths 428, 424, 430, 426 into the exhaust facilities via the chamber exhaust 408. Since the second ports of the second and third valves 424, 426 open into the processing chamber 402 below the pedestal 404, the residual gas A exiting from the second ports of the second and third valves 424, 426 does not react with the substrate 406.

During the transition, the gas divert paths 428, 424, 430, 426 divert gas flow away from the process volume to the chamber exhaust 408 and represents a less-restrictive path to the chamber exhaust 408 relative to the hole pattern of the showerhead 400. Subsequently, the first ports (and optionally the second ports) of the second and third valves 424, 426 are closed, and gas B is dispersed from the plenum 410 via the outlets in the faceplate 412 towards the substrate 406. The process is repeated when transitioning from gas B to gas A.

During each transition, the gas divert paths 428, 424, 430, 426 provide paths for the gas in the plenum 410 to exit the showerhead 400 such that the paths do not go to the substrate 406 (i.e., does not go to the process volume between the showerhead 400 and the substrate 406). The gas divert paths 428, 424, 430, 426 allow for the gas in the plenum 410 to leave the plenum 410 downstream relatively quickly and represent a minimal dead-leg between the second and third valves 424, 426 and the process volume, leaving only the volume of the holes in the faceplate 412, instead of the entire showerhead 400, as a dead leg.

In some implementations, the second and third valves 424, 426 may be omitted. The gas from the plenum 410 can exit through passages 428, 430 into a region of the processing chamber 402 below the pedestal 404 and can flow towards the chamber exhaust 408 without reacting with the substrate 406.

FIG. 4A shows an example of a bore-less showerhead 450 with chamber walls defining a bore 451 and with a gas divert path downstream from the showerhead 450 according to the present disclosure. The showerhead 450 comprises a plenum 452 and a faceplate 454 including a plurality of outlets or features (e.g., slots or through holes).

A first valve (also called an ALD valve as described above) 456 is arranged at an edge or the center of a processing chamber (e.g., element 102 shown in FIG. 1A) proximate to an inlet 460 of the showerhead 450. The inlet 460 is proximate to the plenum 452. A first passage 462 in the showerhead 450 between the inlet 460 and the plenum 452 connects the inlet 460 to the plenum 452.

A first port of the first valve 456 is connected to a gas supply (e.g., element 130 shown in FIG. 1A) via a first gas line 464. A second port of the first valve 456 is connected to the inlet 460 via a second gas line 466. The first valve 456 is not connected to the exhaust facilities to which a chamber exhaust (e.g., similar to element 408 shown in FIG. 3C) is connected.

The showerhead 450 includes an outlet 468 at an opposite end relative to the inlet 460. The outlet 468 is proximate to the plenum 452. A second valve 472 is arranged at an opposite end of the showerhead 450 relative to the first valve 456. The second valve 472 is proximate to the edge of the processing chamber. A second passage 470 in the showerhead 450 between the outlet 468 and the plenum 452 connects the outlet 468 to the plenum 452. A first port of the second valve 472 is connected to the outlet 468 via a third gas line 474. A second port of the second valve 472 is connected via a fourth gas line 476 to the exhaust facilities to which the chamber exhaust is connected.

The second passage 470, the third gas line 474, and the second valve 472 constitute a gas divert path for the showerhead 450. The gas divert path formed by the second passage 470, the third gas line 474, and the second valve 472 (hereinafter the gas divert path 470, 474, 472) is integral to the showerhead 450 and is downstream from the plenum 452 of the showerhead 450.

During ALD processing, in each ALD cycle, the showerhead 450 receives gas A followed by gas B from the gas supply via the first valve 456 through the first and second gas lines 464, 466. The gases enter the showerhead 450 through the inlet 460 and the first passage 462 into the plenum 452. A controller (e.g., element 160 shown in FIG. 1A) controls the first and second valves 456, 472 and operates the ports of the first and second valves 456, 472 as follows.

When receiving each gas, the first and second ports of the first valve 456 are open, and the first port of the second valve 472 is closed. The second port of the second valve 472 may be open or closed. The showerhead 450 disperses each gas via the outlets in the faceplate 454 towards a substrate 480 arranged on a pedestal 482 in the processing chamber.

When transitioning from gas A to gas B in an ALD cycle, gas B is flowed through the first and second ports of the first valve 456, the first and second gas lines 464, 466, the inlet 460, and the first passage 462 into the plenum 452. The first port (and the second port, if closed) of the second valve 472 is/are opened to connect the plenum 452 to the gas divert path 470, 474, 472. The residual gas A in the plenum 452 is diverted through the gas divert path 470, 474, 472 and via the fourth gas line 476 into the exhaust facilities.

During the transition, the gas divert path 470, 474, 472 diverts gas flow away from the process volume to the chamber exhaust and represents a less-restrictive path to the chamber exhaust relative to the hole pattern of the showerhead 450.

Subsequently, the first port (and optionally the second port) of the second valve 472 is closed, and gas B is dispersed from the plenum 452 via the outlets in the faceplate 454 towards the substrate 480. The process is repeated when transitioning from gas B to gas A.

During each transition, the gas divert path 470, 474, 472 provides a path for the gas in the plenum 452 to exit the showerhead 450 such that the path does not go to the substrate 480 (i.e., does not go to the process volume between the showerhead 450 and the substrate 480). The gas divert path 470, 474, 472 allows for the gas in the plenum 452 to leave the plenum 452 downstream relatively quickly and represents a minimal dead-leg between the second valve 472 and the process volume, leaving only the volume of the holes in the faceplate 454, instead of the entire showerhead 450, as a dead leg.

FIG. 4B shows an example of a bore-less showerhead 500 with chamber walls defining a bore 501 and with a gas divert path through valves at the bottom of the bore 501 according to the present disclosure. During transition, the gas exits through the bottom of the bore 501 into a region of the processing chamber below a pedestal 504 arranged in a processing chamber (e.g., similar to element 102 shown in FIG. 1A). Since the gas exits though the bottom of the bore 501 into the region below the pedestal 504, the gas exiting the gas divert path does not react with a substrate 506 arranged on the pedestal 504. Instead, the gas from the gas divert path exits the processing chamber through a chamber exhaust (e.g., similar to element 408 shown in FIGS. 3A-3C).

The showerhead 500 comprises a plenum 510 and a faceplate 512 including a plurality of outlets or features (e.g., slots or through holes). The showerhead 500 comprises an inlet 514 proximate to the plenum 510. A first passage 516 in the showerhead 500 between the inlet 514 and the plenum 510 connects the inlet 514 to the plenum 510.

A first valve (also called an ALD valve as described above) 518 is arranged at an edge or the center of the processing chamber proximate to the inlet 514 of the showerhead 500. A first port of the first valve 518 is connected to a gas supply (e.g., element 130 shown in FIG. 1A) via a first gas line 520. A second port of the first valve 518 is connected to the inlet 514 via a second gas line 522. The first valve 518 is not connected to the exhaust facilities to which the chamber exhaust is connected.

A second valve 524 and a third valve 526 are arranged at the bottom of the bore 501 at opposite ends. Second and third passages 528 and 530 in the bore 501 are respectively connected to the first ports of the second and third valves 524, 526. Second and third passages 528 and 530 in the bore 501 are also respectively connected fourth and fifth passages 529 and 531 in the showerhead 500, which in turn are respectively connected to first and second opposite ends of the plenum 510.

For example, to connect the second passage 528 in the bore 501 to the fourth passage 529 in the showerhead 500, there may be a hole and a slot respectively in the bore 501 and showerhead 500 (or vice versa) that mate with each other, with a seal surrounding the hole and the slot. Similarly, to connect the third passage 530 in the bore 501 to the fifth passage 531 in the showerhead 500, there may be a hole and a slot respectively in the bore 501 and showerhead 500 (or vice versa) that mate with each other, with a surrounding seal.

Thus, the first end of the plenum 510 is connected to the first port of the second valve 524 via the fourth passage 529 in the showerhead 500 and the second passage 528 in the bore 501; and the second end of the plenum 510 is connected to the first port of the third valve 526 via the fifth passage 531 in the showerhead 500 and the third passage 530 in the bore 501. Second ports of the second and third valves 524, 526 are configured to open into the processing chamber and are in fluid communication with the chamber exhaust connected to the exhaust facilities.

The fourth, second, fifth, and third passages 529, 528, 531, 530, and the second and third valves 524, 526 constitute gas divert paths for the showerhead 500. The gas divert paths formed by the fourth, second, fifth, and third passages 529, 528, 531, 530 and the second and third valves 524, 526 (hereinafter the gas divert paths 529, 528, 524, 531, 530, 526) are integral to the showerhead 500 and is downstream from the plenum 510 of the showerhead 500.

During ALD processing, in each ALD cycle, the showerhead 500 receives gas A followed by gas B from the gas supply via the first valve 518 through the first and second gas lines 520, 522. The gases enter the showerhead 500 through the inlet 514 and the first passage 516 into the plenum 510. A controller (e.g., element 160 shown in FIG. 1A) controls the first, second, and third valves 518, 524, 526 and operates the ports of the first, second, and third valves 518, 524, 526 as follows.

When receiving each gas, the first and second ports of the first valve 518 are open, and the first ports of the second and third valves 524, 526 are closed. The second ports of the second and third valves 524, 526 may be open or closed. The showerhead 500 disperses each gas via the outlets in the faceplate 512 towards the substrate 506 arranged on the pedestal 504 in the processing chamber.

When transitioning from gas A to gas B in an ALD cycle, gas B is flowed through the first and second ports of the first valve 518, the first and second gas lines 520, 522, the inlet 514, and the first passage 516 into the plenum 510. The first ports (and the second ports, if closed) of the second and third valves 524, 526 are opened to connect the plenum 510 to the gas divert path gas divert paths 529, 528, 524, 531, 530, 526. The residual gas A in the plenum 510 is diverted through the gas divert paths 529, 528, 524, 531, 530, 526 into the exhaust facilities via the chamber exhaust. Since the second ports of the second and third valves 524, 526 open into the processing chamber below the pedestal 504, the residual gas A exiting from the second ports of the second and third valves 524, 526 does not react with the substrate 506.

During the transition, the gas divert paths 529, 528, 524, 531, 530, 526 divert gas flow away from the process volume to the chamber exhaust and represent a less-restrictive path to the chamber exhaust relative to the hole pattern of the showerhead 500. Subsequently, the first ports (and optionally the second ports) of the second and third valves 524, 526 are closed, and gas B is dispersed from the plenum 510 via the outlets in the faceplate 512 towards the substrate 506. The process is repeated when transitioning from gas B to gas A.

During each transition, the gas divert paths 529, 528, 524, 531, 530, 526 provide paths for the gas in the plenum 510 to exit the showerhead 500 such that the paths do not go to the substrate 506 (i.e., does not go to the process volume between the showerhead 400 and the substrate 506). The gas divert paths 529, 528, 524, 531, 530, 526 allow for the gas in the plenum 510 to leave the plenum 510 downstream relatively quickly and represent a minimal dead-leg between the second and third valves 524, 526 and the process volume, leaving only the volume of the holes in the faceplate 512, instead of the entire showerhead 500, as a dead leg.

In some implementations, the second and third valves 524, 526 may be omitted. The gas from the plenum 510 can exit through passages 528, 530 into a region of the processing chamber below the pedestal 504 and can flow towards the chamber exhaust without reacting with the substrate 506.

FIG. 5A shows an example of a showerhead 550 according to the present disclosure. The showerhead 550 is attached to the top of a processing chamber 551 (e.g., element 102 shown in FIG. 1A), of which only top and side walls are shown. The showerhead 550 is either mounted flush (i.e., directly) to the top of the processing chamber 551 or using a stem portion 553 like a chandelier. The showerhead 550 comprises a plenum 552 and a faceplate 554 including a plurality of outlets or features (e.g., slots or through holes). The showerhead 550 includes a gas divert path downstream from the plenum 552 according to the present disclosure.

A first valve (also called an ALD valve as described above) 556 is arranged at an edge or the center of the processing chamber 551 proximate to an inlet 560 of the showerhead 550. The inlet 560 is proximate to the plenum 552. A first port of the first valve 556 is connected to a gas supply (e.g., element 130 shown in FIG. 1A) via a first gas line 564. A second port of the first valve 556 is connected to the chamber wall via a second gas line 566. The first valve 556 is not connected to the exhaust facilities to which a chamber exhaust is connected.

A second valve 572 is arranged at an opposite end of the showerhead 550 relative to the first valve 556. The second valve 572 is proximate to the edge of the processing chamber 551 and to an outlet 568 of the showerhead 550. A first port of the second valve 572 is connected to chamber wall via a third gas line 574. A second port of the second valve 572 is connected via a fourth gas line 576 to the exhaust facilities to which the chamber exhaust is connected.

A first passage 562 in the showerhead 550 between the inlet 560 and a first end of the plenum 552 connects the inlet 560 to the first end of the plenum 552. A second passage 570 in the showerhead 550 between the outlet 568 and a second end of the plenum 552 that is opposite to the first end connects the outlet 568 to the second end of the plenum 552. A third passage 567 in the chamber wall is connected to the second gas line 566. A fourth passage 569 in the chamber wall is connected to the third gas line 574.

When the showerhead 550 is connected to the processing chamber 551 by the stem portion 553, a fifth gas line 571 is connected between the inlet 560 and the third passage 567 in the chamber wall; and a sixth gas line 573 is connected between the outlet 568 and the fourth passage 569 in the chamber wall. Thus, when the showerhead 550 is connected to the processing chamber 551 by the stem portion 553, the second port of the first valve 556 is connected to the inlet 560 of the showerhead 550 via the second gas line 566, the third passage 567 in the chamber wall, and the fifth gas line 571; and the second port of the second valve 572 is connected to the outlet 568 of the showerhead 550 via the third gas line 574, the fourth passage 569 in the chamber wall, and the sixth gas line 573.

When the showerhead 550 is mounted flush (i.e., directly) to the processing chamber 551 without the stem portion 553, the fifth and sixth gas lines 571, 573 are omitted. The third passage 567 in the chamber wall is connected to the first passage 562 in the showerhead 550 at the inlet 560, and the fourth passage 569 in the chamber wall is connected to the second passage 570 in the showerhead 550 at the outlet 568. For example, at each of the inlet 560 and the outlet 568, there may be a hole and a slot respectively in the chamber wall and the showerhead 550 (or vice versa) that mate with each other, with a seal surrounding the hole and the slot.

Thus, when the showerhead 550 is mounted flush to the processing chamber 551, the second port of the first valve 556 is connected to the first end of the plenum 552 via the second gas line 566, the third passage 567 in the chamber wall, and the first passage 562 in the showerhead 550; and the second port of the second valve 572 is connected to the second end of the plenum 552 via the third gas line 574, the fourth passage 569 in the chamber wall, and the second passage 570 in the showerhead 550.

The second passage 570 in the showerhead 550, the sixth gas line 573 when present (depending on whether the showerhead 550 is mounted to the processing chamber 551 directly or via the stem portion 553), the fourth passage 569 in the chamber wall, the third gas line 574, and the second valve 572 constitute a gas divert path for the showerhead 550. The gas divert path formed by the second passage 570, the sixth gas line 573 when present, the fourth passage 569, the third gas line 574, and the second valve 572 (hereinafter the gas divert path 570, 573, 569, 574, 572) is integral to the showerhead 550 and is downstream from the plenum 552 of the showerhead 550.

During ALD processing, in each ALD cycle, the showerhead 550 receives gas A followed by gas B from the gas supply via the first valve 556 through the first and second gas lines 564, 566, the third passage 567, and the fifth gas line 571 when present. The gases enter through the inlet 560 and the first passage 562 into the plenum 552. A controller (e.g., element 160 shown in FIG. 1A) controls the first and second valves 556, 572 and operates the ports of the first and second valves 556, 572 as follows.

When receiving each gas, the first and second ports of the first valve 556 are open, and the first port of the second valve 572 is closed. The second port of the second valve 572 may be open or closed. The showerhead 550 disperses each gas via the outlets in the faceplate 554 towards a substrate 580 arranged on a pedestal 582 in the processing chamber 551.

When transitioning from gas A to gas B in an ALD cycle, gas B is flowed through the first and second ports of the first valve 556, the first and second gas lines 564, 560, the third passage 567, the fifth gas line 571 when present, the inlet 560, and the first passage 562 into the plenum 552. The first port (and the second port, if closed) of the second valve 572 is/are opened to connect the plenum 552 to the gas divert path 570, 573, 569, 574, 572. The residual gas A in the plenum 552 is diverted through the gas divert path 570, 573, 569, 574, 572 and through the fourth gas line 576 into the exhaust facilities.

During the transition, the gas divert path 570, 573, 569, 574, 572 diverts gas flow away from the process volume to the chamber exhaust and represents a less-restrictive path to the chamber exhaust relative to the hole pattern of the showerhead 550. Subsequently, the first port (and optionally the second port) of the second valve 572 is closed, and gas B is dispersed from the plenum 552 via the outlets in the faceplate 554 towards the substrate 580. The process is repeated when transitioning from gas B to gas A.

During each transition, the gas divert path 570, 573, 569, 574, 572 provides a path for the gas in the plenum 552 to exit the showerhead 550 such that the path does not go to the substrate 580 (i.e., does not go to the process volume between the showerhead 550 and the substrate 580). The gas divert path 570, 573, 569, 574, 572 allows for the gas in the plenum 552 to leave the plenum 552 downstream relatively quickly and represents a minimal dead-leg between the second valve 572 and the process volume, leaving only the volume of the holes in the faceplate 554, instead of the entire showerhead 550, as a dead leg.

FIG. 5B shows an example of a showerhead 600 with a gas divert path downstream from the showerhead 600 according to the present disclosure. The showerhead 600 is attached to the top of a processing chamber 601 (e.g., element 102 shown in FIG. 1A), of which only top and side walls are shown. The showerhead 600 is either mounted flush (i.e., directly) to the top of the processing chamber 601 or using a stem portion 603 like a chandelier.

An outer diameter of the showerhead 600 is greater than that of a pedestal 604 arranged in the processing chamber 601. During transition, the gas exits through the periphery of the showerhead 600 into the processing chamber 601. Since the showerhead 600 is greater in diameter than the pedestal 604, the gas exiting through the periphery of the showerhead 600 tends to flow towards the bottom of the processing chamber 601 without reacting with a substrate 506 arranged on the pedestal 504. The gas exiting through the periphery of the showerhead 600 flows towards the bottom of the processing chamber 601 and exits the processing chamber 601 through a chamber exhaust (e.g., similar to element 408 shown in FIGS. 3A-3C).

The showerhead 600 comprises a plenum 610 and a faceplate 612 including a plurality of outlets or features (e.g., slots or through holes). The showerhead 600 comprises an inlet 614 proximate to the plenum 610. A first passage 616 in the showerhead 500 between the inlet 614 and the plenum 610 connects the inlet 614 to the plenum 610. The showerhead 600 comprises outlets 615 and 617 at first and second opposite ends of the showerhead 600. Second and third passages 619 and 621 in the showerhead 500 between the outlets 615 and 617 and the opposite ends of the plenum 610 respectively connect the outlets 615 and 617 to the plenum 610.

A first valve (also called an ALD valve as described above) 618 is arranged at an edge or the center of the processing chamber 601 proximate to the inlet 614 of the showerhead 500. A first port of the first valve 618 is connected to a gas supply (e.g., element 130 shown in FIG. 1A) via a first gas line 620. A second port of the first valve 618 is connected to the chamber wall via a second gas line 622. A fourth passage 623 in the chamber wall is connected to the second gas line 622. The first valve 614 is not connected to the exhaust facilities to which the chamber exhaust is connected.

When the showerhead 600 is connected to the processing chamber 601 by the stem portion 603, a third gas line 625 is connected between the inlet 614 and the fourth passage 623 in the chamber wall. Thus, when the showerhead 600 is connected to the processing chamber 601 by the stem portion 603, the second port of the first valve 618 is connected to the inlet 614 of the showerhead 600 via the second gas line 622, the fourth passage 623 in the chamber wall, and the third gas line 625.

When the showerhead 600 is mounted flush (i.e., directly) to the processing chamber 601 without the stem portion 603, the third gas line 625 is omitted. The fourth passage 623 in the chamber wall is connected to the first passage 616 in the showerhead 600 at the inlet 614. For example, at the inlet 614, there may be a hole and a slot respectively in the chamber wall and the showerhead 600 (or vice versa) that mate with each other, with a seal surrounding the hole and the slot. Thus, when the showerhead 600 is mounted directly to the processing chamber 601, the second port of the first valve 618 is connected to the first end of the plenum 610 via the second gas line 622, the fourth passage 623 in the chamber wall, and the first passage 616 in the showerhead 600.

In this implementation, the second and third passages 619, 621 in the showerhead 600 and the outlets 615, 617 of the showerhead 600 constitute gas divert paths for the showerhead 600. The gas divert paths formed by the second and third passages 619, 621 and the outlets 615, 617 (hereinafter the gas divert paths 619, 615, 621, 617) are integral to the showerhead 600 and are downstream from the plenum 610 of the showerhead 600.

In another implementation, second and third valves 624 and 626 may arranged proximate to the outlets 615 and 617 of the plenum 610, respectively. First ports of the second and third valves 624 and 626 may be connected to the outlets 615 and 617 via fourth and fifth gas lines 628 and 630, respectively. Second ports of the second and third valves 624 and 626 are configured to open into the processing chamber 601 and are in fluid communication with the chamber exhaust connected to the exhaust facilities. Again, since the diameter of the showerhead 600 is greater than that of the pedestal 604, the gas exiting the second ports of the second and third valves 624 and 626 does not react with the substrate 606 on the pedestal, and flows towards the bottom of the processing chamber 601 and exits via the chamber exhaust.

In this other implementation including the second and third valves 624, 626, the second and third passages 619 and 621 in the showerhead 600, the fourth and fifth gas lines 628 and 630, and the second and third valves 624 and 626 constitute gas divert paths for the showerhead 600. The gas divert paths formed by the second and third passages 619, 621, the fourth and fifth gas lines 628, 630, and the second and third valves 624, 626 (hereinafter the gas divert paths 619, 628, 624, 621, 630, 626) are integral to the showerhead 600 and are downstream from the plenum 610 of the showerhead 600.

During ALD processing, in each ALD cycle, the showerhead 600 receives gas A followed by gas B from the gas supply via the first valve 618 through the first and second gas lines 620, 622, the fourth passage 623, and the third gas line 625 when present (i.e., when the showerhead is mounted with the stem portion 603). The gases enter through the inlet 614 and the first passage 616 into the plenum 610. A controller (e.g., element 160 shown in FIG. 1A) controls and operates the ports of the first valve 618 and the second and third valves 624, 626 when present as follows.

When receiving each gas, the first and second ports of the first valve 618 are open, and the first ports of the second and third valves 624, 626 (when used) are closed. The second ports of the second and third valves 624, 526 may be open or closed. When the second and third valves 624, 626 are absent, the outlets 615 and 617 of the showerhead 600 are in fluid communication with the processing chamber 601. The showerhead 600 disperses each gas via the outlets in the faceplate 612 towards the substrate 606 arranged on the pedestal 504 in the processing chamber 601.

When transitioning from gas A to gas B in an ALD cycle, gas B is flowed through the first and second ports of the first valve 618, the first and second gas lines 620, 622, the fourth passage 623, the third gas line 625 when present, the inlet 614, and the first passage 616 into the plenum 610. When the second and third valves 624, 626 are not used, the residual gas A in the plenum 610 is diverted through the passages 619, 621 and the outlets 615, 617 (i.e., through the gas divert paths 619, 615, 621, 617) into the processing chamber 601 and onward to the exhaust facilities via the chamber exhaust. Alternatively, when the second and third valves 624, 626 are used, the first ports (and the second ports, if closed) of the second and third valves 624, 626 are opened to connect the plenum 610 to the gas divert paths 619, 628, 624, 621, 630, 626. The residual gas A in the plenum 610 is diverted through the gas divert paths 619, 628, 624, 621, 630, 626 into the exhaust facilities via the chamber exhaust.

During the transition, the gas divert paths 619, 615, 621, 617 (or the gas divert paths 619, 628, 624, 621, 630, 626) divert gas flow away from the process volume to the chamber exhaust and represent a less-restrictive path to the chamber exhaust relative to the hole pattern of the showerhead 600. Subsequently, gas B is dispersed from the plenum 610 via the outlets in the faceplate 612 towards the substrate 606. Alternatively, when the second and third valves 624, 626 are used, the first ports (and optionally the second ports) of the second and third valves 624, 626 are closed, and gas B is dispersed from the plenum 610 via the outlets in the faceplate 612 towards the substrate 606. The process is repeated when transitioning from gas B to gas A.

During each transition, the gas divert paths 619, 615, 621, 617 (or the gas divert paths 619, 628, 624, 621, 630, 626) provide paths for the gas in the plenum 610 to exit the showerhead 600 such that the paths do not go to the substrate 606 (i.e., does not go to the process volume between the showerhead 600 and the substrate 606). The gas divert paths 619, 615, 621, 617 (or the gas divert paths 619, 628, 624, 621, 630, 626) allow for the gas in the plenum 610 to leave the plenum 610 downstream relatively quickly and represent a minimal dead-leg between the outlets 615, 617 and the process volume, or between the second and third valves 624, 626 and the process volume, leaving only the volume of the holes in the faceplate 612, instead of the entire showerhead 600, as a dead leg.

FIG. 6 shows a method 650 of operating the showerheads shown in FIGS. 3A-5B to provide the gas divert path downstream from the showerhead according to the present disclosure. For example, the method 650 can be performed by a controller (e.g., element 160 shown in FIG. 1A) during an ALD process performed in a processing chamber (e.g., element 102 shown in FIG. 1A) using any of the showerheads shown in FIGS. 3A-5B. In the following description, the term control refers to an operation performed by the controller.

At 652, control opens an inlet valve (e.g., the ALD valve 356, 418, 456, 518, 556, or 618 shown in FIGS. 3A-5B) and closes the outlet valve or valves (e.g., elements 372, 424 and 426, 472, 524 and 526, 572, or 624 and 626 shown in FIGS. 3A-5B). At 654, control supplies a gas (e.g., gas A) to an inlet of the showerhead (e.g., elements 360, 414, 460, 514, 560, or 614 shown in FIGS. 3A-5B) via the inlet valve.

At 656, control determines if time to switch gas supply (i.e., transition from supplying gas A to gas B) has arrived. Control returns to 654 if the time to switch gas supply has not arrived. Control proceeds to 658 if time to switch gas supply has arrived.

At 658, control opens the outlet valve or valves. If the configuration shown in FIG. 5B does not include the valves 624, 624, control skips this step and proceeds to 660. At 660, control switches gas supply (i.e., supplies gas B) to the inlet of the showerhead via the inlet valve. At 662, control closes the outlet valve or valves after a predetermined time has elapsed after opening the valve or valves. Again, if the configuration shown in FIG. 5B does not include the valves 624, 624, control skips this step and proceeds to 664.

At 664, control determines if the process being performed in the processing chamber using the showerhead (e.g., ALD) is complete. Control returns to 656 and continues switching the gases supplied to the showerhead until the process is complete. Control ends when the process is complete. By thus controlling the output valve or valves located downstream from the showerheads during gas transitions, the method 650 provides a gas divert path or paths downstream from the showerheads as described above.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another are within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead for a processing chamber, the showerhead comprising:
a body having upper, lower, and side surfaces defining a plenum;
a plurality of through holes provided on the lower surface of the body, the plurality of through holes being in fluid communication with the plenum and the processing chamber;
an inlet provided on one of the upper and side surfaces of the body;
a first passage provided in the body, the first passage connecting the inlet to the plenum;
an outlet provided on one of the upper and side surfaces of the body; and
a second passage provided in the body, the second passage connecting the outlet to the plenum.

2. The showerhead of claim 1 wherein the outlet is downstream relative to the inlet and is in fluid communication with the inlet.

3. The showerhead of claim 1 wherein the inlet and the outlet are located on opposite ends of the showerhead.

4. The showerhead of claim 1 wherein the inlet and the outlet are connected to opposite ends of the plenum.

5. The showerhead of claim 1 wherein the inlet and the outlet are located on opposite ends of the showerhead and are connected to opposite ends of the plenum.

6. A system comprising:
the showerhead of claim 1; and
first and second valves respectively connected to the inlet and the outlet;
wherein the first valve is connected to a gas supply; and
wherein the second valve is connected to an exhaust of the processing chamber.

7. The system of claim 6 further comprising a controller configured to:
close the second valve and open the first valve to supply a first gas from the gas supply to the inlet;
open the second valve when subsequently supplying a second gas instead of the first gas from the gas supply to the inlet via the first valve; and
close the second valve after a predetermined time.

8. The showerhead of claim 1 wherein:
the side surface extends perpendicularly towards a bottom of the processing chamber; and
wherein the outlet is located on a bottom end of the side surface.

9. The showerhead of claim 8 wherein the bottom end of the side surface extends past at least a portion of a pedestal arranged in the processing chamber.

10. A system comprising:
the showerhead of claim 8; and
first and second valves respectively connected to the inlet and the outlet;
wherein the first valve is connected to a gas supply; and
wherein the second valve is in fluid communication with an exhaust of the processing chamber.

11. The system of claim 10 further comprising a controller configured to:
close the second valve and open the first valve to supply a first gas from the gas supply to the inlet;
open the second valve when subsequently supplying a second gas instead of the first gas from the gas supply to the inlet via the first valve; and
close the second valve after a predetermined time.

12. The showerhead of claim 1 wherein the lower surface is attached to a sidewall of the processing chamber.

13. The showerhead of claim 12 wherein the outlet is located on a bottom end of the sidewall.

14. A system comprising:
the showerhead of claim 13; and
first and second valves respectively connected to the inlet and the outlet;
wherein the first valve is connected to a gas supply; and
wherein the second valve is in fluid communication with an exhaust of the processing chamber located at a bottom of the processing chamber.

15. The system of claim 14 further comprising a controller configured to:
close the second valve and open the first valve to supply a first gas from the gas supply to the inlet;
open the second valve when subsequently supplying a second gas instead of the first gas from the gas supply to the inlet via the first valve; and
close the second valve after a predetermined time.

16. The showerhead of claim 1 wherein the showerhead is mounted to a top plate of the processing chamber and has a greater diameter than a pedestal arranged in the processing chamber.

17. A system comprising:
the showerhead of claim 16; and
first and second valves arranged on the top plate and are respectively connected to the inlet and the outlet;
wherein the first valve is connected to a gas supply; and
wherein the second valve is connected to an exhaust of the processing chamber.

18. The system of claim 17 further comprising a controller configured to:
close the second valve and open the first valve to supply a first gas from the gas supply to the inlet;
open the second valve when subsequently supplying a second gas instead of the first gas from the gas supply to the inlet via the first valve; and
close the second valve after a predetermined time.

19. A system comprising:
the showerhead of claim 16; and
a first valve arranged on the top plate;
wherein the first valve is connected to the inlet and to a gas supply; and
wherein the outlet is located on a periphery of the showerhead.

20. The system of claim 19 further comprising:
a second valve connected to the outlet, wherein the second valve is in fluid communication with an exhaust of the processing chamber located at a bottom of the processing chamber.

21. The system of claim 20 further comprising a controller configured to:
close the second valve and open the first valve to supply a first gas from the gas supply to the inlet;
open the second valve when subsequently supplying a second gas instead of the first gas from the gas supply to the inlet via the first valve; and
close the second valve after a predetermined time.
